(19) United States
(12) Patent Application Publication
(10) Pub. No.: US 2026/0038535 A1
(43) Pub. Date: Feb. 5, 2026

(54) SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Hyunho Kim, Suwon-si (KR); Eunhyun Kim, Suwon-si (KR); Hyung Joon Kim, Suwon-si (KR)

(21) Appl. No.: 19/053,170

(22) Filed: Feb. 13, 2025

(30) Foreign Application Priority Data
Aug. 1, 2024 (KR) 10-2024-0102720

(51) Int. Cl. G11C 5/06; H01L 23/00; H01L 25/065; H01L 25/18; H10B 43/10; H10B 43/27; H10B 43/35; H10B 43/40; H10B 80/00; H10D 80/30

(52) U.S. Cl. CPC G11C 5/06; H01L 25/0652; H01L 25/18; H10B 43/10; H10B 43/27; H10B 43/35; H10B 43/40; H10D 80/30; H01L 24/32; H01L 2224/32145; H01L 2224/32225; H01L 2225/06524; H01L 2225/06541; H01L 2924/1438; H10B 80/00

(57) ABSTRACT

A semiconductor memory device includes a substrate including a cell array region and an extension region, gate electrodes on the substrate, a channel structure on the cell array region, and an insulating pattern. The gate electrodes are alternately stacked in a first direction, providing a staircase structure on the extension region. The channel structure penetrates the gate electrodes. A first through via penetrates first and second gate electrodes. The first through via, disposed between the first gate electrode and the substrate, is connected to the first gate electrode. The insulating pattern includes: an insulating structure; a liner insulating layer; and a capping pattern disposed between the insulating structure and a sidewall of the first through via. A width of a capping layer of the capping pattern decreases as a distance from the first through via increases.

### CROSS-REFERENCE TO RELATED APPLICATION

This application claims priority to Korean Patent Application No. 10-2024-0102720, filed in the Korean Intellectual Property Office on Aug. 1, 2024, the entire contents of which are hereby incorporated by reference.

### BACKGROUND

Semiconductor memory devices with high-capacity data storage are in demand. One method for increasing the data storage capacity includes arranging memory cells three-dimensionally instead of two-dimensionally.

### SUMMARY

In the process of forming a first through via, a capping pattern can be disposed on a first insulating layer and a second insulating layer to prevent penetration of the first through via. In addition, the dielectric constant of a first capping layer is lower than that of a second capping layer. An insulating pattern may include the first capping layer having a relatively low dielectric constant, thereby improving insulating characteristics between a second gate electrode and the first through via. Accordingly, electrical characteristics and the reliability of the semiconductor memory device and an electronic system including the semiconductor memory device can be improved.

In a first general aspect, a semiconductor memory device includes: a substrate including a cell array region and an extension region; a plurality of gate electrodes on the substrate, wherein the plurality of gate electrodes are alternately stacked in a first direction perpendicular to an upper surface of the substrate, and the plurality of gate electrodes are disposed in a staircase structure on the extension region; a channel structure on the cell array region, wherein the channel structure is formed through the plurality of gate electrodes and extends in the first direction; a first through via on the extension region, wherein the first through via is formed through a first gate electrode of the plurality of gate electrodes and a second gate electrode of the plurality of gate electrodes, which is disposed between the first gate electrode and the substrate, and wherein the first through via is connected to the first gate electrode; and an insulating pattern disposed between the second gate electrode and a sidewall of the first through via, wherein the insulating pattern includes: an insulating structure disposed on a sidewall of the second gate electrode; a liner insulating layer disposed on an upper surface of the insulating structure; and a capping pattern disposed between the insulating structure and the sidewall of the first through via, the insulating structure includes a first insulating layer and a second insulating layer surrounding the first insulating layer, the capping pattern includes a first capping layer disposed on the insulating structure, and a second capping layer disposed between the first capping layer and the sidewall of the first through via, and a width of the second capping layer in the first direction decreases as a distance from the first through via increases.

In a second general aspect, a semiconductor memory device includes: a substrate including a cell array region and an extension region; a mold structure on the substrate, wherein the mold structure includes a plurality of gate electrodes and a plurality of mold insulating layers which are alternately stacked in a first direction perpendicular to an upper surface of the substrate, and the plurality of gate electrodes include a pad portion disposed in a staircase structure on the extension region; a channel structure on the cell array region, wherein the channel structure is formed through the plurality of gate electrodes and extends in the first direction; a first through via on the extension region, wherein the first through via is formed through a pad portion of a first gate electrode of the plurality of gate electrodes and through a second gate electrode of the plurality of gate electrodes, which is disposed between the first gate electrode and the substrate, and wherein the first through via is electrically connected to the pad portion of the first gate electrode; and an insulating pattern disposed between the second gate electrode and the first through via and surrounding a portion of a sidewall of the first through via, wherein the insulating pattern includes: an insulating structure including a first insulating layer and a second insulating layer surrounding three surfaces of the first insulating layer; and a capping pattern disposed between the insulating structure and the sidewall of the first through via, the capping pattern includes a first capping layer covering a first side of an insulating structure defined by a side surface of the first insulating layer and a side surface of the second insulating layer, and a second capping layer disposed between the first capping layer and the sidewall of the first through via, and a width of the second capping layer in the first direction decreases as a distance from the first through via increases.

In a third general aspect, an electronic system including: a first substrate; a semiconductor memory device on the first substrate, wherein the semiconductor memory device includes a peripheral circuit structure, and a cell structure stacked on the peripheral circuit structure; and a controller on the first substrate, wherein the controller is electrically connected to the semiconductor memory device, wherein the cell structure includes: a second substrate including a cell array region and an extension region; a plurality of gate electrodes on the second substrate, wherein the plurality of gate electrodes are alternately stacked in a first direction perpendicular to an upper surface of the second substrate, and the plurality of gate electrodes are disposed in a staircase structure on the extension region; a channel structure on the cell array region, wherein the channel structure is formed through the plurality of gate electrodes and extends in the first direction; a first through via formed through a first gate electrode of the plurality of gate electrodes and through a second gate electrode of the plurality of gate electrodes, which is disposed between the first gate electrode and the second substrate, wherein the first through via is connected to the first gate electrode; and an insulating pattern disposed between the second gate electrode and a sidewall of the first through via, the first through via is formed through the second substrate and connected to the peripheral circuit structure, the insulating pattern includes: an insulating structure disposed on a sidewall of the second gate electrode and including a first insulating layer and a second insulating layer surrounding the first insulating layer; a liner insulating layer disposed on an upper surface of the insulating structure; and a capping pattern disposed between the insulating structure and the sidewall of the first through via, the capping pattern includes a first capping layer disposed on the insulating structure, and a second capping layer disposed between the first capping layer and the sidewall of the first through via, and a width of the second capping layer in the first direction decreases as a distance from the first through via increases.

### BRIEF DESCRIPTION OF THE DRAWINGS

FIG. 1 is a plan view of an example of a semiconductor memory device.

FIG. 2 is a cross-sectional view taken along line A-A of FIG. 1.

FIG. 3 is a cross-sectional view taken along line B-B of FIG. 1.

FIG. 4 is an enlarged view of a region Q1 of FIG. 2.

FIG. 5 is an enlarged view of a region Q2 of FIG. 2.

FIGS. 6, 7, 8, 9, 10, 11, 12, and 13 are diagrams of examples of the region Q1.

FIG. 14 depicts an example of a semiconductor memory device.

FIG. 15 depicts another example of a semiconductor memory device.

FIG. 16 is another example of a cross-sectional view taken along line A-A of FIG. 1.

FIGS. 17-30 are diagrams illustrating intermediate manufacturing stages of a region Q3 from FIG. 16.

FIG. 31 is a block diagram of an example of an electronic system.

FIG. 32 is an example of a perspective view of an electronic system including a semiconductor memory device.

FIG. 33 is a schematic cross-sectional view taken along line V-V of FIG. 32.

### DETAILED DESCRIPTION

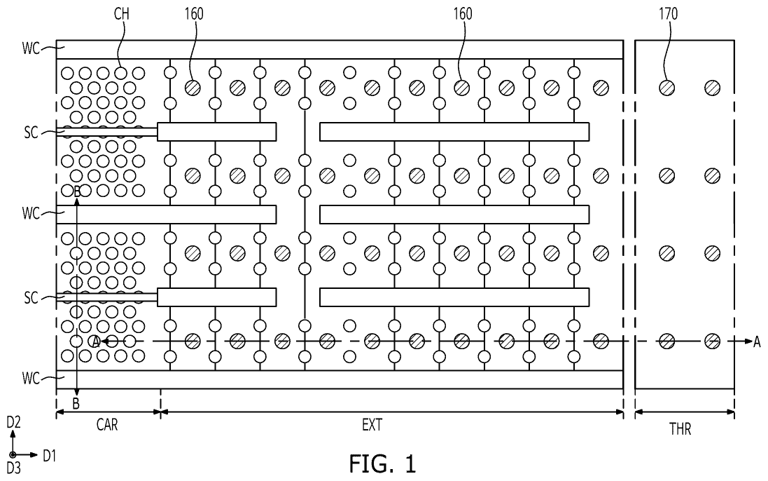

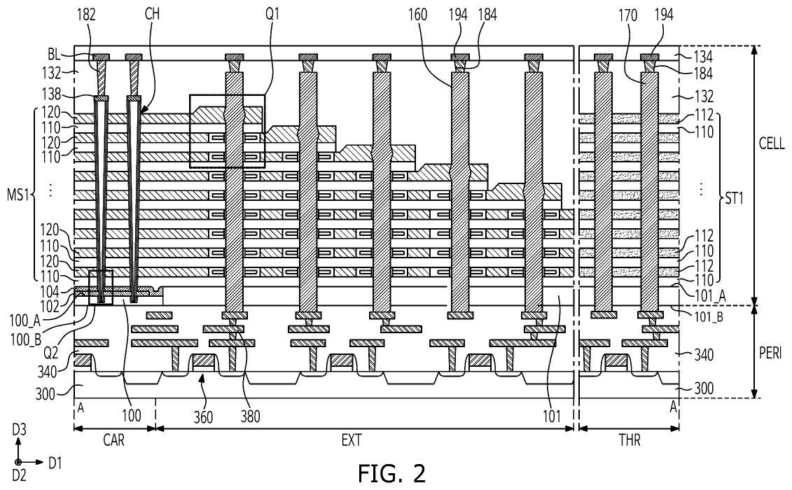

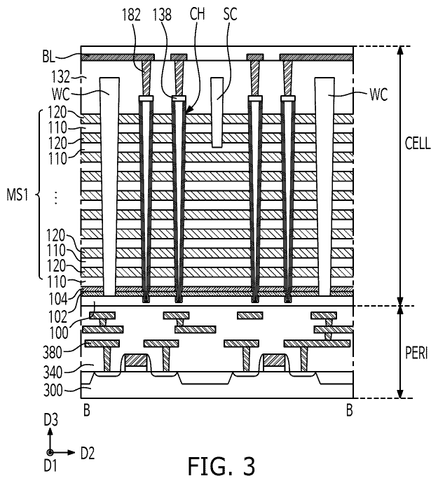

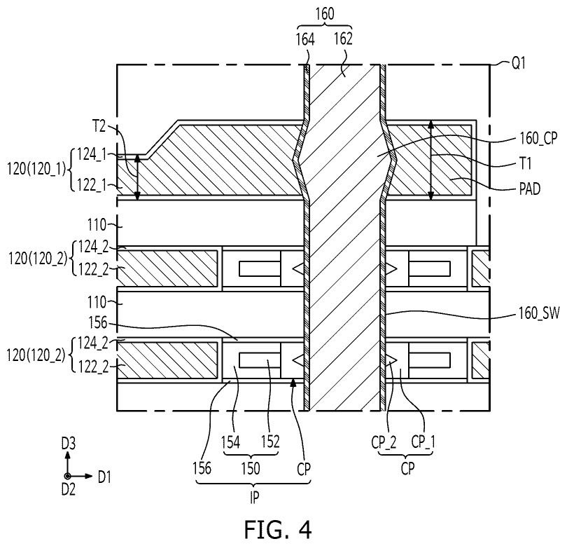

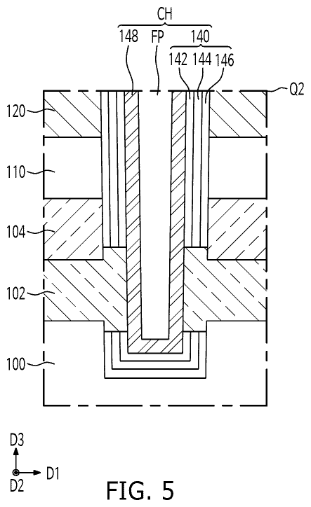

FIG. 1 is a plan view of an example of a semiconductor memory device. FIG. 2 is a cross-sectional view taken along line A-A of FIG. 1. FIG. 3 is a cross-sectional view taken along line B-B of FIG. 1. FIG. 4 is an enlarged view of a region Q1 of FIG. 2. FIG. 5 is an enlarged view of a region Q2 of FIG. 2.

Referring to FIGS. 1 to 5, a semiconductor memory device includes a cell structure CELL and a peripheral circuit structure PERI.

The cell structure CELL may include a cell substrate 100, an insulating substrate 101, a first mold structure MS1, an insulating pattern IP, a channel structure CH, a first through via 160, a second through via 170, a bit line BL, etc.

The substrate may include a cell array region CAR, an extension region EXT, and a through region THR. The substrate may include the cell substrate 100 and the insulating substrate 101. The cell substrate 100 may be provided on the cell array region CAR.

A memory cell array including a plurality of memory cells may be formed on the cell array region CAR. The extension region EXT may be disposed around the cell array region CAR. For example, the extension region EXT may surround the cell array region CAR. The through region THR may be disposed outside the extension region EXT. For example, the through region THR may be disposed on one side of the extension region EXT, but the present disclosure is not limited thereto.

For example, the cell substrate 100 may include a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate, etc. In some implementations, the cell substrate 100 may include polysilicon (poly Si).

The cell substrate 100 may include a first side 100_A and a second side 100_B opposite the first side 100 A. The first side 100_A of the cell substrate 100 may be a side on which the first mold structure MS1 and the channel structure CH are disposed. The first side 100_A of the cell substrate 100 may be referred to as a front side of the cell substrate 100. The second side 100_B of the cell substrate 100 may be referred to as a back side of the cell substrate 100.

The insulating substrate 101 may be provided on the extension region EXT and the through region THR. The insulating substrate 101 may include a first side 101_A and a second side 101_B opposite the first side 101_A. The first side 101_A of the insulating substrate 101 may be a side on which the first mold structure MS1 and a first stack ST1 are disposed. The first side 101_A of the insulating substrate 101 may be referred to as a front side of the insulating substrate 101. The second side 101_B of the insulating substrate 101 may be referred to as a back side of the insulating substrate 101.

For example, the insulating substrate 101 may include at least one of silicon oxide, silicon nitride, silicon oxynitride, and silicon carbide, but the present disclosure is not limited thereto.

Although it is illustrated that the second side 101_B of the insulating substrate 101 is disposed on the same plane as the second side 100_B of the cell substrate 100, this is only an example. As another example, the second side 101_B of the insulating substrate 101 may be lower than the second side 100_B of the cell substrate 100.

The first mold structure MS1 may be formed on the first side 100_A of the cell substrate 100. The first mold structure MS1 may include a plurality of mold insulating layers 110 and a plurality of gate electrodes 120, which are alternately stacked in a third direction D3. Each of the mold insulating layers 110 and each of the gate electrodes 120 may have a layered structure extending parallel to the first side 100_A of the cell substrate 100. The gate electrodes 120 may be stacked on the cell substrate 100 while being spaced apart from each other by the mold insulating layer 110, e.g., the gate electrodes 120 and the mold insulating layers 110 are stacked in alternating order.

In some implementations, some of the gate electrodes 120 of the plurality of gate electrodes 120 may be used as a ground select line GSL and an erase control line ECL of the semiconductor memory device. For example, the gate electrodes 120 of the plurality of gate electrodes 120, which are adjacent to source layers 102 and 104, may be used as the erase control line ECL. The erase control line ECL may be used as a gate electrode of an erase transistor. The erase transistor may generate Gate Induced Drain Leakage (GIDL) to perform an erase operation on a plurality of memory cell transistors. A gate electrode 120, which is adjacent to the erase control line ECL, may be provided as a ground select line GSL. However, the present disclosure is not limited thereto. The arrangement and number of the ground select lines GSL may vary.

In some implementations, some of the plurality of gate electrodes 120 may be provided as a string select line SSL of the semiconductor memory device. For example, the gate electrodes 120 of the plurality of gate electrodes 120, which are adjacent to the bit line BL, may be provided as the string select line SSL. However, the present disclosure is not limited thereto. The arrangement and number of string select lines SL may vary.

The mold insulating layer 110 may include an insulating material. For example, the mold insulating layer 110 may include at least one of silicon oxide, silicon nitride, and silicon oxynitride, but the present disclosure is not limited thereto.

The plurality of mold insulating layers 110 and the plurality of gate electrodes 120 may be stacked in a stepwise manner on the extension region EXT. For example, one end of the plurality of mold insulating layers 110 and one end of the plurality of gate electrodes 120 may be disposed in a staircase structure on the extension region EXT. The plurality of gate electrodes 120 may extend to different lengths in a first direction D1 and a second direction D2 to have a step difference. In some implementations, the plurality of gate electrodes 120 may include a pad portion PAD disposed in a staircase structure.

The first through via 160 may be disposed on the extension region EXT. The first through via 160 may be formed through the first mold structure MS1 and the insulating substrate 101 to be electrically connected to the peripheral circuit structure PERI. The first through via 160 may be connected to a first gate electrode 120_1 of the plurality of gate electrodes 120.

The first through via 160 may include a conductive pillar 162 and a barrier conductive film 164. The conductive pillar 162 may extend in the third direction D3. The barrier conductive film 164 may be disposed on a side surface of the conductive pillar 162. The barrier conductive film 164 may surround the conductive pillar 162.

The conductive pillar 162 and the barrier conductive film 164 may include a conductive material. For example, the conductive pillar 162 may include a metal such as tungsten, nickel, cobalt, and tantalum, a metal silicide such as tungsten silicide, nickel silicide, cobalt silicide, tantalum silicide, doped polysilicon, or a combination thereof. For example, the barrier conductive film 164 may include titanium nitride, tantalum nitride, tungsten nitride, or a combination thereof.

The plurality of gate electrodes 120 may include the first gate electrode 120_1 and a second gate electrode 120_2. The first gate electrode 120_1 may be electrically connected to the first through via 160. For example, the first through via 160 may be formed through the pad portion PAD of the first gate electrode 120_1. The first through via 160 may be connected to the pad portion PAD of the first gate electrode 120_1. The pad portion PAD of the first gate electrode 120_1 may surround the first through via 160. The pad portion PAD of the first gate electrode 120_1 may be in contact with the barrier conductive film 164.

The first gate electrode 120_1 may include a first filling conductive layer 122_1 and a first liner dielectric layer 124_1. The first filling conductive layer 122_1 may extend in the first direction D1. The first liner dielectric layer 124_1 may surround the first filling conductive layer 122_1. The first liner dielectric layer 124_1 may not be disposed between the pad portion PAD of the first gate electrode 120_1 and the first through via 160.

In some implementations, a thickness T1 of the pad portion PAD of the first gate electrode 120_1 may be greater than a thickness T2 of a plate of the first gate electrode 120_1. The thickness may refer to a thickness in the third direction D3.

In some implementations, the first through via 160 may include a connection portion 160_CP. The connection portion 160_CP of the first through via 160 may protrude toward the first gate electrode 120_1. The connection portion 160_CP of the first through via 160 may overlap the pad portion PAD of the first gate electrode 120_1 in the first direction D1. The first liner dielectric layer 124_1 may not be disposed on the connection portion 160_CP of the first through via 160. In other words, the connection portion 160_CP of the first through via 160 may be in contact with the first filling conductive layer 122_1.

The first through via 160 may be formed through the second gate electrode 120_2. The second gate electrode 120_2 may be prevented from being electrically connected to the first through via 160 by the insulating pattern IP. The second gate electrode 120_2 may be the gate electrode 120, of the plurality of gate electrodes 120, which is disposed between the substrates 100 and 101 and the first gate electrode 120_1.

The second gate electrode 120_2 may include a second filling conductive layer 122_2 and a second liner dielectric layer 124_2. The second filling conductive layer 122_2 may extend in the first direction D1. The second liner dielectric layer 124_2 may surround the second filling conductive layer 122_2.

The filling conductive layers 122_1 and 122_2 may include a conductive material. For example, the filling conductive layers 122_1 and 122_2 may include a metal such as tungsten, cobalt, and nickel, or a semiconductor material such as silicon, but the present disclosure is not limited thereto.

The liner dielectric layers 124_1 and 124_2 may include silicon oxide, silicon nitride, or metal oxide having a higher dielectric constant than the dielectric constant of silicon oxide. The metal oxide may include hafnium oxide, aluminum oxide, zirconium oxide, tantalum oxide, or a combination thereof.

The insulating pattern IP may be disposed between the second gate electrode 120_2 and the first through via 160. The insulating pattern IP may be disposed on a sidewall 160_SW of the first through via 160. The insulating pattern IP may have a shape of a ring surrounding a portion of the sidewall 160_SW of the first through via 160. The insulating pattern IP may overlap the second gate electrode 120_2 in the first direction D1. The second gate electrode 120_2 may be spaced apart from the first through via 160 by the insulating pattern IP.

The insulating pattern IP may include an insulating structure 150, a capping pattern CP, and a liner insulating layer 156.

The insulating structure 150 may include a first insulating layer 152 and a second insulating layer 154. The insulating structure 150 may be disposed on a sidewall of the second gate electrode 120_2. A first side of the insulating structure 150 may be in contact with the second gate electrode 120_2. A second side of the insulating structure 150 may be in contact with the capping pattern CP. The second side of the insulating structure 150 may be defined by a side surface of the first insulating layer 152 and a side surface of the second insulating layer 154.

When viewed in a cross section, the first side and the second side of the insulating structure 150 may face each other in the first direction D1.

The second insulating layer 154 may surround the first insulating layer 152. For example, the second insulating layer 154 may surround three surfaces of the first insulating layer 152. The second insulating layer 154 may expose at least one surface of the first insulating layer 152.

The capping pattern CP may be disposed between the insulating structure 150 and the first through via 160. The capping pattern CP may be disposed on the sidewall 160_SW of the first through via 160. The capping pattern CP may be in contact with the first through via 160. The capping pattern CP may be disposed on the second side of the insulating structure 150. The capping pattern CP may cover the second side of the insulating structure 150. The capping pattern CP may be in contact with each of the first insulating layer 152 and the second insulating layer 154.

The liner insulating layer 156 may be disposed on the insulating structure 150 or the capping pattern CP. The liner insulating layer 156 may be disposed between the mold insulating layer 110 disposed on the second gate electrode 120_2 and the insulating structure 150. The liner insulating layer 156 may be disposed between the mold insulating layer 110 disposed on the second gate electrode 120_2 and the insulating structure 150 and between the mold insulating layer 110 disposed on the second gate electrode 120_2 and the capping pattern CP. The liner insulating layer 156 may extend, e.g., be elongated, in the first direction DI along an upper surface of the insulating structure 150 and an upper surface of the capping pattern CP. The liner insulating layer 156 may extend in the first direction along a lower surface of the insulating structure 150 and a lower surface of the capping pattern CP. The liner insulating layer 156 may not be disposed between the second gate electrode 120_2 and the second insulating layer 154.

The capping pattern CP may include a first capping layer CP_1 disposed on the insulating structure 150, and a second capping layer CP_2 disposed between the first capping layer CP_1 and the sidewall 160_SW of the first through via 160. The first capping layer CP_1 may be in contact with the first insulating layer 152 and the second insulating layer 154 of the insulating structure 150. In some implementations, a width of the second capping layer CP_2 in the third direction D3 may decrease as the distance from the first through via 160 increases. For example, the second capping layer CP_2 may have a wedge shape. However, the shape of the second capping layer CP_2 is not limited thereto, and the shape of the second capping layer CP_2 may vary.

In some implementations, the second capping layer CP_2 may cover at least a portion of the sidewall 160_SW of the first through via 160 exposed between the liner insulating layers 156. The sidewall 160_SW of the first through via 160 exposed between the liner insulating layers 156 may refer to a portion overlapping the insulating structure 150 in the first direction D1. As illustrated, the first capping layer CP_1 and the second capping layer CP_2 may cover the sidewall 160_SW of the first through via 160 exposed between the liner insulating layers 156.

The first insulating layer 152 and the second insulating layer 154 may include an insulating material. The insulating material of the first insulating layer 152 and the insulating material of the second insulating layer 154 may have different etch selectivities. In some implementations, the first insulating layer 152 may include any one of silicon nitride and silicon oxynitride, and the second insulating layer 154 may include silicon oxide. However, the present disclosure is not limited thereto.

The liner insulating layer 156 may include an insulating material. For example, the liner insulating layer 156 may be formed of a single film or multiple layers (composite layers) of silicon oxynitride or silicon nitride.

The first capping layer CP_1 and the second capping layer CP_2 may include an insulating material. The insulating material of the first capping layer CP_1 may have a different etch selectivity from the insulating material of the second capping layer CP_2. In some implementations, the first capping layer CP_1 may include silicon oxide, and the second capping layer CP_2 may include any one of silicon nitride and silicon oxynitride. However, the present disclosure is not limited thereto.

The channel structure CH may be formed through the first mold structure MS1. For example, the channel structure CH may be formed through and intersect each of the plurality of mold insulating layers 110 and the plurality of gate electrodes 120. The channel structure CH may be disposed in a first channel hole extending in the third direction D3. The channel structure CH may have a pillar shape (e.g., a cylindrical shape) extending in the third direction D3. In some implementations, the cross section of the channel structure CH may have an inclined side surface such that its width is progressively narrowed toward the cell substrate 100. However, the present disclosure is not limited thereto.

The channel structure CH may include an information storage film 140, a semiconductor pattern 148, and a filling pattern FP.

The semiconductor pattern 148 may extend in the third direction D3 through the first mold structure MS1. Although the semiconductor pattern 148 of FIG. 5 has a cup shape, e.g., being wider with increasing distance from the cell substrate 100, the present disclosure is not limited thereto. For example, the semiconductor pattern 148 may have various shapes such as a cylindrical shape, a rectangular prism shape, a filled pillar shape, etc. For example, the semiconductor pattern 148 may include a semiconductor material such as a single crystal silicon, a polycrystalline silicon, an organic semiconductor material, a carbon nanostructure, etc., although the present disclosure is not limited thereto.

The information storage film 140 may be interposed between the semiconductor pattern 148 and each of the gate electrodes 120. For example, the information storage film 140 may extend along an outer surface of the semiconductor pattern 148. For example, the information storage film 140 may include at least one of silicon oxide, silicon nitride, silicon oxynitride, and a high-k material having a higher dielectric constant than the silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

In some implementations, the channel structures CH may be disposed in a zigzag form. For example, as illustrated in FIG. 1, the channel structures CH may be disposed to cross each other in the first direction DI and the second direction D2. The channel structures CH disposed in the zigzag form may further improve the integration density of the semiconductor memory device. In some implementations, the channel structures CH may be arranged in a honeycomb form.

In some implementations, the information storage film 140 may include multiple films. The information storage film 140 may include a tunnel insulating film 142, a charge storage film 144, and a blocking insulating film 146, which may be stacked in order on the outer surface of the semiconductor pattern 148.

For example, the tunnel insulating film 142 may include the silicon oxide or a high-k material (e.g., aluminum oxide (Al₂O₃), hafnium oxide (HfO₂)) having a higher dielectric constant than the dielectric constant of silicon oxide. For example, the charge storage film 144 may include silicon nitride. For example, the blocking insulating film 146 may include the silicon oxide or a high-k material (e.g., aluminum oxide (Al₂O₃) or hafnium oxide (HfO₂)) having a higher dielectric constant than the silicon oxide.

In some implementations, the channel structure CH may further include a filling pattern FP. The filling pattern FP may be formed to fill the inside of the cup-shaped semiconductor pattern 148. For example, the filling pattern FP may include an insulating material such as silicon oxide, but the present disclosure is not limited thereto.

A channel pad 138 may be disposed on the channel structure CH. The channel pad 138 may be disposed on the channel structure CH and electrically connected to the semiconductor pattern 148. For example, the channel pad 138 may include polysilicon doped with an impurity. However, the present disclosure is not limited thereto.

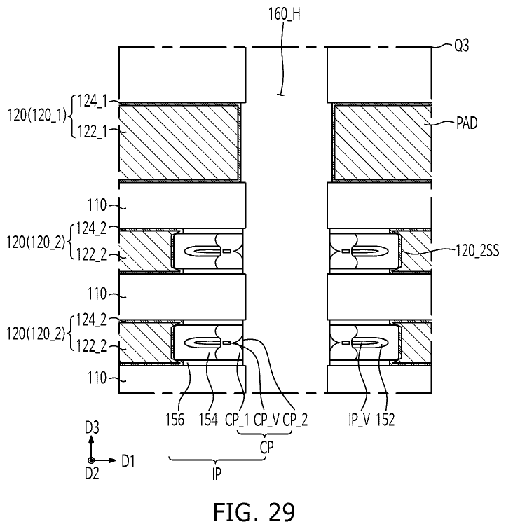

In some implementations, the source layers 102 and 104 may be formed on the cell substrate 100. The source layers 102 and 104 may be disposed between the cell substrate 100 and the first mold structure MS1. For example, the source layers 102 and 104 may extend along the first side 100_A of the cell substrate 100. The source structures 102 and 104 may be formed such that they are connected to the semiconductor pattern 148 and/or the information storage film 140 of the channel structure CH. The source layers 102 and 104 may be used as a common source line (e.g., CSL of FIG. 29) of the semiconductor memory device. For example, the source layers 102 and 104 may include polysilicon or metal doped with an impurity, but the present disclosure is not limited thereto.

In some implementations, the channel structure CH may be formed through the source layers 102 and 104. For example, a lower portion of the channel structure CH may be formed through the source layers 102 and 104 and disposed in the cell substrate 100.

In some implementations, the source layers 102 and 104 may include multiple films. For example, the source layers 102 and 104 may include a first source layer 102 and a second source layer 104, which are sequentially stacked on the cell substrate 100. Each of the first source layer 102 and the second source layer 104 may include polysilicon doped with an impurity or polysilicon undoped with an impurity, but the present disclosure is not limited thereto. The first source layer 102 may be in contact with the semiconductor pattern 148 and provided as a common source line (e.g., CSL of FIG. 29) of the semiconductor memory device. The second source layer 104 may be used as a support layer for preventing the mold stack from collapsing or falling in a replacement process for forming the first source layer 102.

In some implementations, a base insulating film may be interposed between the cell substrate 100 and the source layers 102 and 104. For example, the base insulating film may include at least one of silicon oxide, silicon nitride, and silicon oxynitride, but is not limited thereto.

In some implementations, the source layers 102 and 104 may not be disposed in the extension region EXT where the insulating substrate 101 is formed. Although the first side 101 A of the insulating substrate 101 is disposed on the same plane as upper surfaces of the source layers 102 and 104 in FIG. 2, the present disclosure is not limited thereto. As another example, the first side 101_A of the insulating substrate 101 may be disposed at a higher level than the upper surfaces of the source layers 102 and 104.

A block isolation pattern WC may extend in the first direction D1 to penetrate the first mold structure MS1. At least a portion of the block isolation pattern WC may completely cut through the first mold structure MS1. At least a portion of the block isolation pattern WC may partially cut, e.g., penetrate, the first mold structure MS1.

A string isolation structure SC may extend in the first direction D1 to cut some of the gate electrodes 120. For example, the string isolation structure SC formed in a cell block may cut the string select line. The divided string select lines may independently control each region.

The block isolation pattern WC and the string isolation structure SC may include an insulating material, for example, at least one of silicon oxide, silicon nitride, and silicon oxynitride, but are not limited thereto.

The bit line BL may be formed on the first mold structure MS1. The bit line BL may extend in the second direction D2 and intersect the block isolation pattern WC. In addition, the bit line BL may extend in the second direction D2 and be connected to the plurality of channel structures CH arranged along the second direction D2. For example, a bit line contact 182 connected to an upper portion of each of the channel structures CH may be formed in an interlayer insulating film 132. The bit line BL may be electrically connected to the channel structures CH through the bit line contact 182.

In some implementations, the first stack ST1 may be stacked on the insulating substrate 101 in the through region THR. The first stack ST1 may include a plurality of mold sacrificial films 112 and the plurality of mold insulating layers 110, which are alternately stacked on the insulating substrate 101. Each of the mold sacrificial films 112 and each of the mold insulating layers 110 may have a layered structure extending parallel to an upper surface of the insulating substrate 101. The mold sacrificial films 112 may be spaced apart from each other by the mold insulating layers 110 and sequentially stacked on the insulating substrate 101.

For example, the mold sacrificial film 112 may include an insulating material, for example, at least one of silicon oxide, silicon nitride, and silicon oxynitride, but the material choice is not limited thereto. In some implementations, the mold sacrificial film 112 may include a material having etch selectivity with respect to the mold insulating layer 110. For example, the mold insulating layers 110 may include silicon oxide, and the mold sacrificial films 112 may include silicon nitride.

The interlayer insulating film 132 may be formed on the cell substrate 100 to cover the first mold structure MS1. The interlayer insulating film 132 may be formed on the insulating substrate 101 to cover the first stack ST1. For example, the interlayer insulating film 132 may include at least one of silicon oxide, silicon oxynitride, and a low-k material having a lower dielectric constant than silicon oxide, but the material choice is not limited thereto.

The second through via 170 may be disposed in the through region THR. For example, the second through via 170 may be formed through the first stack ST1 in the through region THR and may extend in the third direction D3. The second through via 170 may be formed through the insulating substrate 101 to be electrically connected to the peripheral circuit structure PERI.

Each of the first through via 160 and the second through via 170 may be connected to an upper wiring structure 194 on the interlayer insulating film 132. For example, a wiring insulating film 134 may be formed on the interlayer insulating film 132. The upper wiring structure 194 may be formed in the wiring insulating film 134. Each of the first through via 160 and the second through via 170 may be connected to the upper wiring structure 194 through a wiring contact 184. In some implementations, the upper wiring structure 194 may be connected to the bit line BL. The upper wiring structure 194 and the wiring contact 184 may include a conductive material. For example, the upper wiring structure 194 and the wiring contact 184 may include tungsten (W) or copper (Cu), but the material choice is not limited thereto.

The peripheral circuit structure PERI may include a peripheral circuit substrate 300, a peripheral circuit element 360, and a peripheral circuit wiring structure 380.

The peripheral circuit substrate 300 may be disposed under the cell substrate 100 and the insulating substrate 101. For example, an upper surface of the peripheral circuit substrate 300 may face the second side 100_B of the cell substrate 100. For example, the peripheral circuit substrate 300 may include a semiconductor substrate such as a silicon substrate, a germanium substrate, or a silicon-germanium substrate. Alternatively, the peripheral circuit substrate 300 may include a silicon-on-insulator (SOI) substrate, a germanium-on-insulator (GOI) substrate, etc.

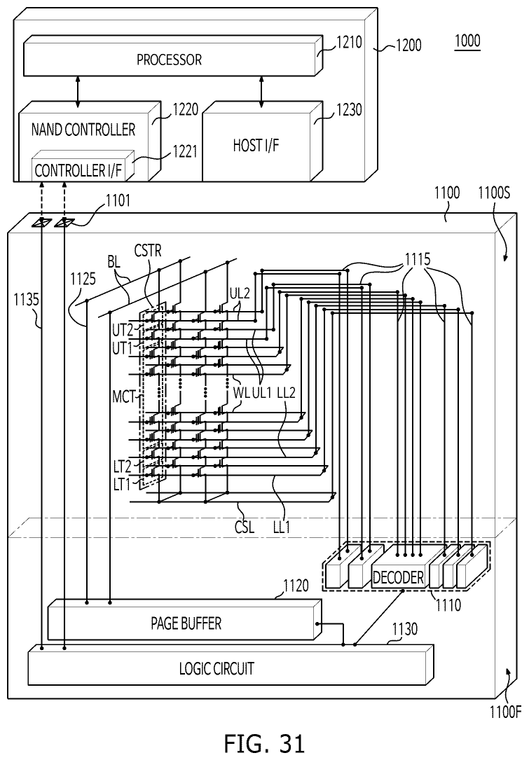

The peripheral circuit element 360 may be formed on the peripheral circuit substrate 300. The peripheral circuit element 360 may configure a peripheral circuit that controls the operation of the semiconductor memory device. For example, the peripheral circuit element 360 may include a logic circuit, a page buffer, a decoder, which will be explained in more detail with reference to FIG. 31. In the following description, a surface of the peripheral circuit substrate 300 with the peripheral circuit element 360 disposed thereon may be referred to as a front side of the peripheral circuit substrate 300. Conversely, a surface of the peripheral circuit substrate 300 opposite to the front side of the peripheral circuit substrate 300 may be referred to as a back side of the peripheral circuit substrate 300.

For example, the peripheral circuit element 360 may include a transistor, but the present disclosure is not limited thereto. For example, the peripheral circuit element 360 may include not only various active elements such as transistors, etc., but also various passive elements such as capacitors, resistors, inductors, etc.

The peripheral circuit wiring structure 380 may be formed on the peripheral circuit element 360. For example, a peripheral wiring insulating film 340 may be formed on the front side of the peripheral circuit substrate 300, and the peripheral circuit wiring structure 380 may be formed in the peripheral wiring insulating film 340. The peripheral circuit wiring structure 380 may be electrically connected to the peripheral circuit element 360. The number and arrangement of the layers of the peripheral circuit wiring structure 380 illustrated herein are merely examples, and the present disclosure is not limited thereto.

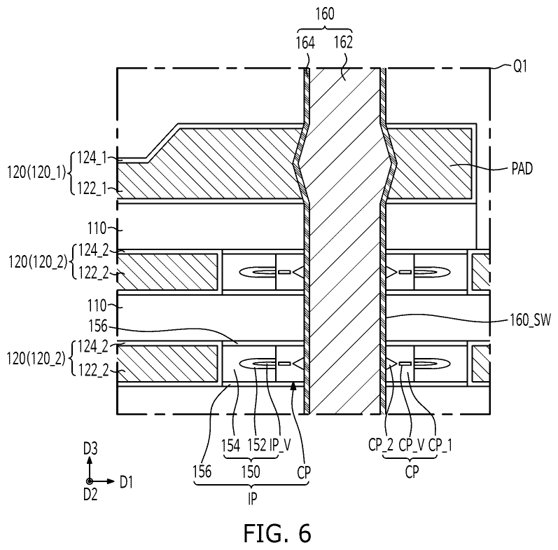

FIG. 6 is a diagram provided to explain a semiconductor memory device. For convenience of description, different configurations from those already described above in FIGS. 1 to 5 will be mainly described.

Referring to FIG. 6, in the semiconductor memory device, the insulating structure 150 may further include a first void IP_V.

The first void IP_V may be formed in the first insulating layer 152. The first insulating layer 152 and the capping pattern CP may surround the first void IP_V. For example, the first insulating layer 152 may surround a portion of the first void IP_V, and the capping pattern CP may be disposed on the insulating structure 150 to cover the first void IP_V. That is, the first insulating layer 152 and the capping pattern CP may completely surround the first void IP_V. The capping pattern CP may prevent other materials from being deposited inside the first void IP_V. The first void IP_V may refer to an empty space. In some implementations, the first void IP_V may be referred to as a seam or an air gap.

The side surface of the first insulating layer 152 may include a curved surface. The side surface of the first insulating layer 152 in contact with the second insulating layer 154 may have a shape convex toward the second insulating layer 154.

In some implementations, the capping pattern CP may further include a second void CP_V.

The second void CP_V may be formed in the first capping layer CP_1. The first capping layer CP_1 may completely surround the second void CP_V. The first capping layer CP_1 may prevent other materials from being deposited inside the second void CP_V. The second void CP_V may refer to an empty space. In some implementations, the second void CP_V may be referred to as a seam or an air gap.

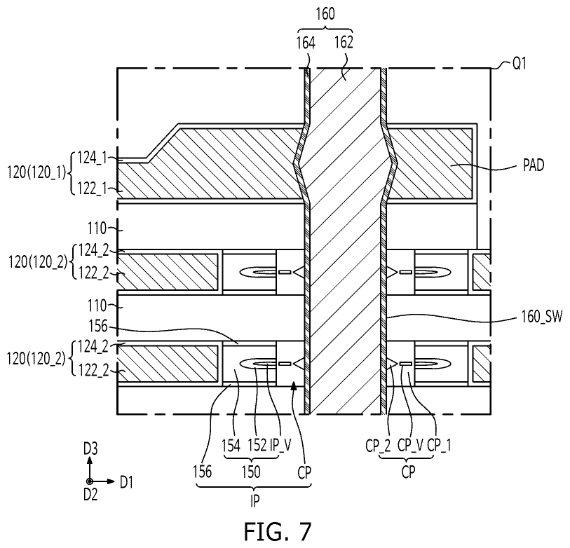

FIG. 7 is a diagram provided to explain a semiconductor memory device. For convenience of description, different configurations from those described above with reference to FIGS. 1 to 6 will be mainly described.

Referring to FIG. 7, in the semiconductor memory device, the liner insulating layer 156 may not be disposed on the upper and lower surfaces of the capping pattern CP. The liner insulating layer 156 may not be disposed between the capping pattern CP and the first mold insulating layer 110. The capping pattern CP may be in contact with the first mold insulating layer 110.

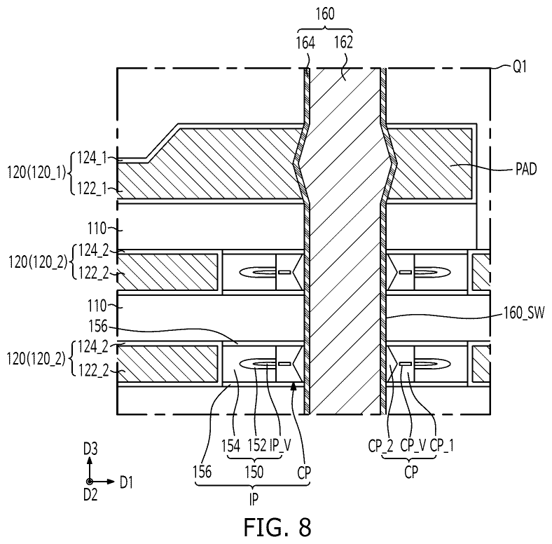

FIG. 8 is a diagram provided to explain a semiconductor memory device. For convenience of description, different configurations from those described above with reference to FIGS. 1 to 6 will be mainly described.

Referring to FIG. 8, in the semiconductor memory device, the second capping layer CP_2 may completely cover the sidewall 160_SW of the first through via 160 exposed between the liner insulating layers 156. The sidewall 160_SW of the first through via 160 exposed between the liner insulating layers 156 may refer to a portion overlapping the insulating structure 150 in the first direction D1.

The second capping layer CP_2 may be disposed between the sidewall 160_SW of the first through via 160 and the first capping layer CP_1. The first capping layer CP_1 may be spaced apart from the first through via 160 by the second capping layer CP_2. The first capping layer CP_1 may not be in contact with the sidewall 160_SW of the first through via 160. In some implementations, the second capping layer CP_2 may be in contact with the liner insulating layer 156.

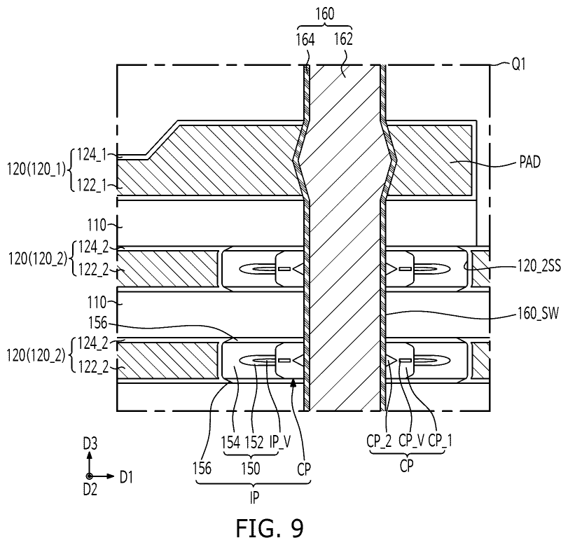

FIG. 9 is a diagram provided to explain a semiconductor memory device. For convenience of description, different configurations from those described above with reference to FIGS. 1 to 6 will be mainly described.

Referring to FIG. 9, in the semiconductor memory device, a side surface 120_2SS of the second gate electrode 120_2 may have a concave shape.

The side surface 120_2SS of the second gate electrode 120_2 may be in contact with the second insulating layer 154 and the liner insulating layer 156. The side surface 120_2SS of the second gate electrode 120_2 may include a concave curved surface. For example, the side surface 120_2SS of the second gate electrode 120_2 may be indented in a direction away from the first through via 160.

The second insulating layer 154 and the liner insulating layer 156 may form a convex curved surface corresponding to the side surface 120_2SS of the second gate electrode 120_2. In other words, a portion of the second insulating layer 154 and a portion of the liner insulating layer 156 may overlap the second gate electrode 120_2 in the third direction D3.

In some implementations, the first capping layer CP_1 may include a convex curved surface protruding toward the insulating structure 150. The first capping layer CP_1 may be in contact with the insulating structure 150 and the liner insulating layer 156. For example, the contact surface between the insulating structure 150 and the first capping layer CP_1 may be indented in a direction away from the first through via 160. In other words, a portion of the second insulating layer 154 may overlap the first capping layer CP_1 in the third direction D3.

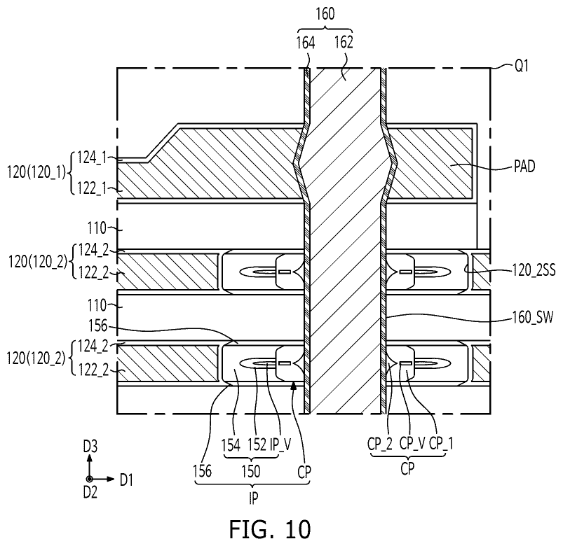

FIG. 10 is a diagram provided to explain a semiconductor memory device. For convenience of description, different configurations from those described above with reference to FIGS. 1 to 9 will be mainly described.

Referring to FIG. 10, in a semiconductor memory device, the second capping layer CP_2 may include a concave curved surface in contact with the first capping layer CP_1. The first capping layer CP_1 may include a convex curved surface corresponding to the concave curved surface of the second capping layer CP_2. When viewed in a cross section, the second capping layer CP_2 may include a wedge shape, e.g., a three-sided shape with two concave sides contacting the first capping layer CP_1 and one straight side contacting the barrier conductive film 164.

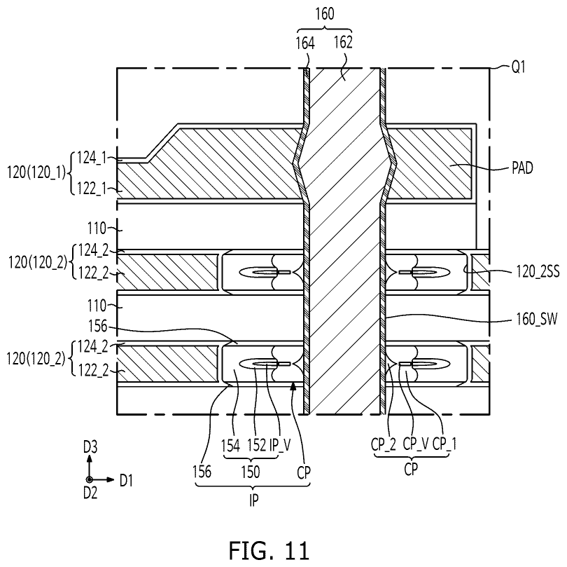

FIG. 11 is a diagram provided to explain a semiconductor memory device. For convenience of description, different configurations from those described above with reference to FIGS. 1 to 5 will be mainly described.

Referring to FIG. 11, in a semiconductor memory device, the contact surface between the first capping layer CP_1 and the insulating structure 150 may include a plurality of curved surfaces.

For example, the contact portion between the first capping layer CP_1 and the second insulating layer 154 of the insulating structure 150 may include a convex curved surface protruding toward the second insulating layer 154, and the contact portion between the first capping layer CP_1 and the first insulating layer 152 of the insulating structure 150 may include a concave curved surface indented from the insulating structure 150. In other words, the first insulating layer 152 of the insulating structure 150 may protrude toward the first capping layer CP_1, and the second insulating layer 154 of the insulating structure 150 may be indented toward the second gate electrode 120_2.

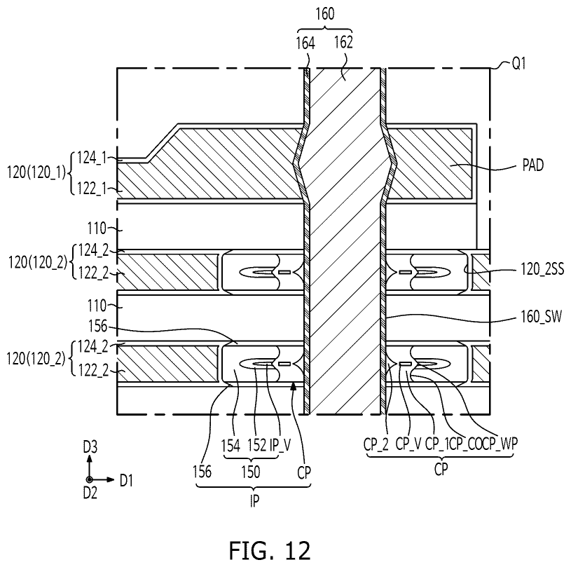

FIG. 12 is a diagram provided to explain a semiconductor memory device. For convenience of description, different configurations from those described above with reference to FIGS. 1 to 5 will be mainly described.

Referring to FIG. 12, in a semiconductor memory device, the first capping layer CP_1 may include an indented portion CP_CO and a wedge pattern CP_WP. The first capping layer CP_1 may be in contact with the first insulating layer 152 and the second insulating layer 154, respectively. The indented portion CP_CO of the first capping layer CP_1 may be in contact with the second insulating layer 154. The indented portion CP_CO of the first capping layer CP_1 may be indented in a direction of approaching the first through via 160. The indented portion CP_CO of the first capping layer CP_1 may include a concave curved surface. The indented portion CP_CO of the first capping layer CP_1 may be disposed on the liner insulating layer 156. The number of indented portions CP_CO of the first capping layer CP_1 may be two.

The wedge pattern CP_WP of the first capping layer CP_1 may be in contact with the first insulating layer 152. A portion of the wedge pattern CP_WP of the first capping layer CP_1 may be disposed in the first void IP_V. The wedge pattern CP_WP of the first capping layer CP_1 may be disposed between first protrusion portions CP_PR of the first capping layer CP_1.

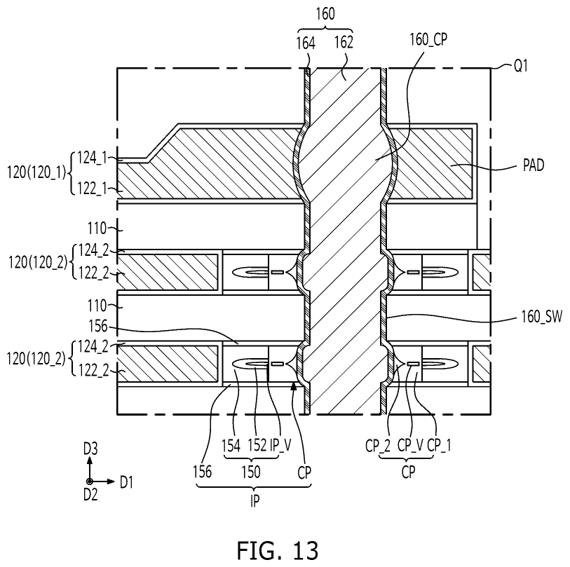

FIG. 13 is a diagram provided to explain a semiconductor memory device. For convenience of description, different configurations from those described above with reference to FIGS. 1 to 9 will be mainly described.

Referring to FIG. 13, in a semiconductor memory device, the first through via 160 may include the connection portion 160_CP and a protrusion portion 160_PR. Each of the connection portion 160_CP and the protrusion portion 160_PR of the first through via 160 may protrude outward from the sidewall 160_SW of the first through via 160.

The connection portion 160_CP of the first through via 160 may protrude toward the first gate electrode 120_1. The connection portion 160_CP of the first through via 160 may include a convex curved surface. The connection portion 160_CP of the first through via 160 may overlap the pad portion PAD of the first gate electrode 120_1 in the first direction D1. The first liner dielectric layer 124_1 may not be disposed on the connection portion 160_CP of the first through via 160. In other words, the connection portion 160_CP of the first through via 160 may be in contact with the first filling conductive layer 122_1.

The protrusion portion 160_PR of the first through via 160 may be disposed on the insulating pattern IP. The protrusion portion 160_PR of the first through via 160 may protrude toward the insulating pattern IP. The protrusion portion 160_PR of the first through via 160 may overlap the insulating pattern IP and the second gate electrode 120_2 in the first direction D1. A degree of protrusion of the protrusion portion 160_PR of the first through via 160 may be less than a degree of protrusion of the connection portion 160_CP of the first through via 160.

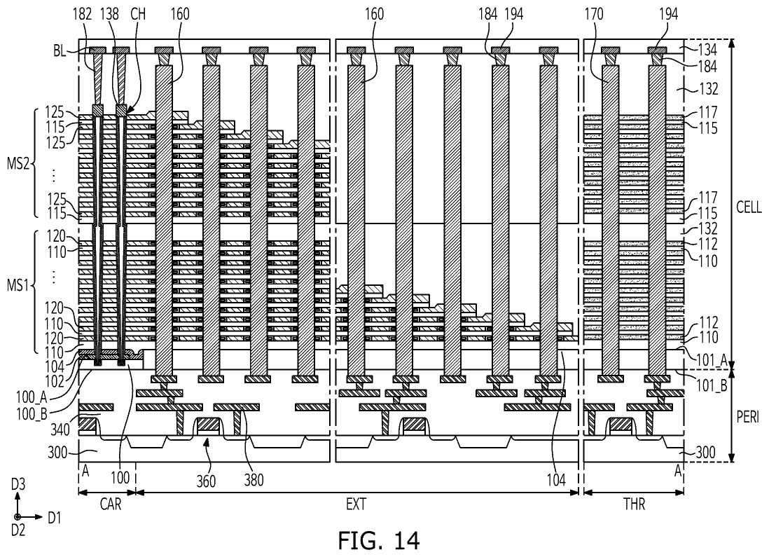

FIG. 14 is a diagram provided to explain a semiconductor memory device. For convenience of description, different configurations from those described above with reference to FIGS. 1 to 5 will be mainly described.

Referring to FIG. 14, in the semiconductor memory device, a second mold structure MS2 and the first mold structure MS1 may be stacked on both the cell substrate 100 and the insulating substrate 101.

The second mold structure MS2 may be disposed on the first mold structure MS1. The second mold structure MS2 may include a plurality of mold insulating layers 115 and a plurality of gate electrodes 125, which are alternately stacked in the third direction D3. Each of the mold insulating layers 115 and each of the gate electrodes 125 may have a layered structure extending parallel to the first side 100_A of the cell substrate 100.

The channel structure CH may extend in the third direction D3 and may be formed through the first mold structure MS1 and the second mold structure MS2. The channel structure CH may have a bent portion between the first mold structure MS1 and the second mold structure MS2.

Although FIG. 12 illustrates that the number of mold structures MS1 and MS2 is two, the present disclosure is not limited thereto. For example, the number of mold structures MS1 and MS2 may be three or four or more.

In the through region THR, the first stack ST1 and a second stack ST2 may be stacked on the insulating substrate 101. The second stack ST2 may be stacked on the first stack ST1. The second stack ST2 may include the plurality of mold insulating layers 115 and a plurality of mold sacrificial films 117, which are alternately stacked on the first stack ST1. The second through via 170 may be formed through the first stack ST1 and the second stack ST2 and extend in the third direction D3.

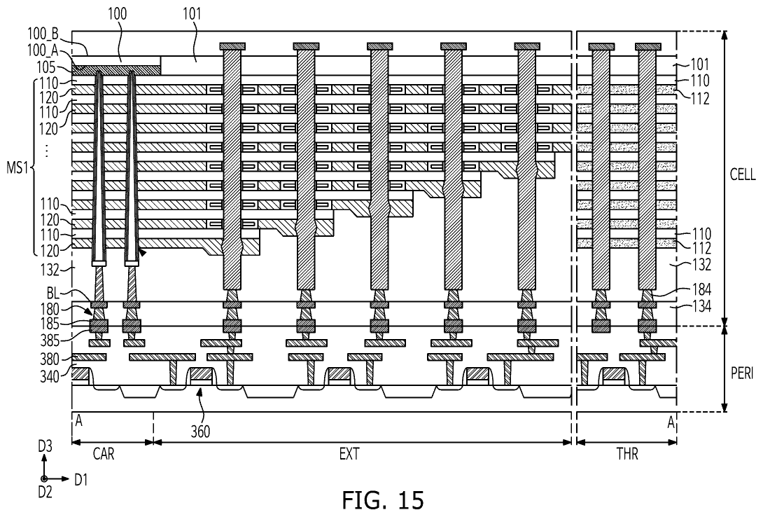

FIG. 15 is a diagram provided to explain a semiconductor memory device. For convenience of description, different configurations from those described above with reference to FIGS. 1 to 5 will be mainly described.

Referring to FIG. 15, the semiconductor memory device may include a common source plate 105.

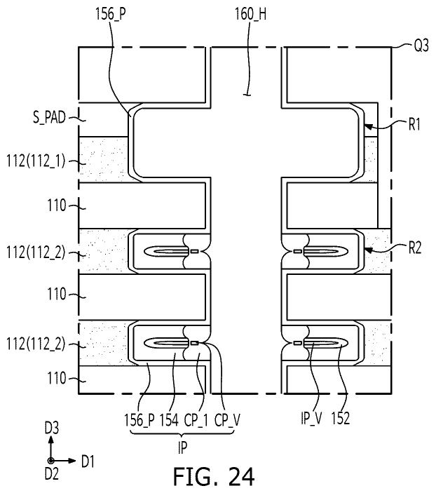

The common source plate 105 may be disposed on the first side 100_A of the cell substrate 100. The common source plate 105 may be connected to the channel structure CH. For example, the common source plate 105 may be electrically connected to the semiconductor pattern of the channel structure CH. The common source plate 105 may be used as a common source line (e.g., CSL of FIG. 24) of the semiconductor memory device. The first mold structure MS1 may be disposed on the common source plate 105. For example, the common source plate 105 may include polycrystalline silicon or metal doped with an impurity, but the present disclosure is not limited thereto.

The semiconductor memory device may have a chip-to-chip (C2C) structure. The C2C structure refers to manufacturing an upper chip including the memory cell structure (CELL) on a first wafer (e.g., the cell substrate 100), manufacturing a lower chip including the peripheral circuit structure (PERI) on a second wafer (e.g., the peripheral circuit substrate 300) that is different from the first wafer, and connecting the upper and lower chips to each other by a bonding method.

In some implementations, a bonding method refers to a method of electrically connecting a first bonding metal 185 formed on the uppermost metal layer of the upper chip and a second bonding metal 385 formed on the uppermost metal layer of the lower chip to each other. For example, if the first bonding metal 185 and the second bonding metal 385 are formed of copper (Cu), the bonding method may be a Cu-Cu bonding method. However, these materials are only an example, and the first bonding metal 185 and the second bonding metal 385 may be formed of various other metals such as aluminum (Al), tungsten (W), etc.

As the first bonding metal 185 and the second bonding metal 385 are bonded to each other, a bonding wiring structure 180 may be connected to the peripheral circuit wiring structure 380. Accordingly, the bit line BL and each of the gate electrodes 120 may be electrically connected to the peripheral circuit element 360.

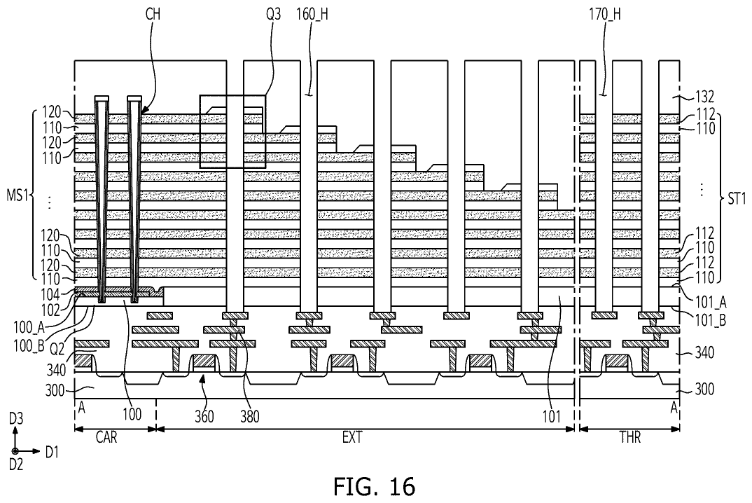

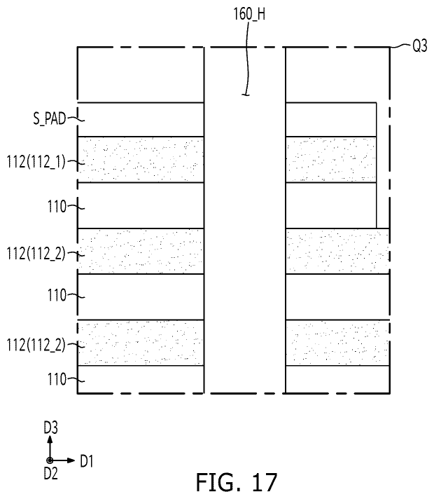

FIG. 16 is an example of a cross-sectional view taken along line A-A of FIG. 1. FIGS. 17 to 30 are enlarged views provided to explain a region Q3 of FIG. 16, which are provided to explain a method for manufacturing a semiconductor memory device.

Referring to FIGS. 16 and 17, a pre-mold structure PMS1 and the first stack ST1 may be formed on the cell substrate 100 and the insulating substrate 101, and a first through via hole 160_H and a second through via hole 170_H may be formed.

In detail, the cell substrate 100 and the insulating substrate 101 may be stacked on the peripheral circuit structure PERI. The peripheral circuit structure PERI may include, on the peripheral circuit substrate 300, the peripheral circuit element 360, the peripheral circuit wiring structure 380, and a peripheral circuit inter-wire insulating film 340. The cell substrate 100 and the insulating substrate 101 may be stacked on the peripheral circuit inter-wire insulating film 340.

The pre-mold structure PMS1 may include the plurality of first mold insulating layers 110 and the plurality of first mold sacrificial films 112, which are alternately stacked on the first side 100_A of the cell substrate 100 and the first side 101_A of the insulating substrate 101. The pre-mold structure PMS1 may be patterned in a staircase structure on the extension region EXT. Accordingly, a portion of a first mold sacrificial film 112 of the pre-mold structure PMS1 may be exposed. A pad sacrificial film S_PAD may be formed on the exposed first mold sacrificial film 112.

For example, the pad sacrificial film S_PAD may be formed on a select mold sacrificial film 112_1 of the first mold sacrificial films 112. In some implementations, the pad sacrificial film S_PAD may be formed by forming an insulating layer (e.g., a silicon nitride layer) covering an exposed upper surface and side surface of the first mold sacrificial film 112 and removing a portion of the insulating layer such that the insulating layer only remains on the exposed upper surface of the first mold sacrificial film 112. A thickness of the pad sacrificial film S_PAD may be about 20% to about 110% of a thickness of the first mold sacrificial film 112, but the present disclosure is not limited thereto. A non-select mold sacrificial film 112_2 may be the first mold sacrificial film 112 of the plurality of first mold sacrificial films 112, which is disposed between the select mold sacrificial film 112_1 and the insulating substrate 101.

The first stack ST1 may include the plurality of first mold insulating layers 110 and the plurality of first mold sacrificial films 112, which are alternately stacked on the first side 101_A of the insulating substrate 101. The first mold sacrificial film 112 may include a material having etch selectivity with respect to the first mold insulating layer 110. For example, the first mold insulating layer 110 may include a silicon oxide film, and the first mold sacrificial film 112 may include a silicon nitride film.

The first through via hole 160_H may be formed through the pre-mold structure PMS1. The first through via hole 160_H may extend in the third direction D3 through the pad sacrificial film S_PAD, the first mold insulating layer 110, the first mold sacrificial film 112, and the insulating substrate 101. A bottom surface of the first through via hole 160_H may expose the peripheral circuit wiring structure 380 of the peripheral circuit structure PERI.

In addition, the second through via hole 170_H may be formed through the first stack ST1. The second through via hole 170_H may extend in the third direction D3 through the first stack ST1 and the insulating substrate 101. A bottom surface of the second through via hole 170_H may expose the peripheral circuit wiring structure 380 of the peripheral circuit structure PERI.

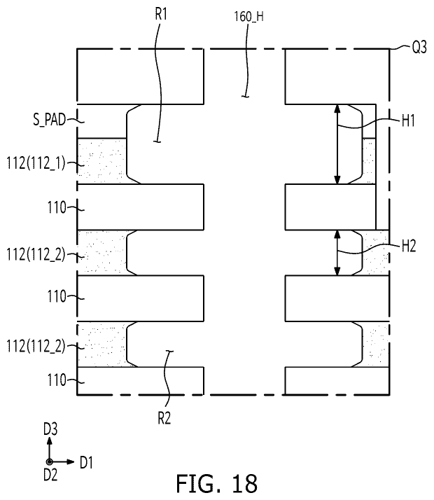

Referring to FIG. 18, a first recess R1 and a second recess R2 may be formed in the mold sacrificial film 112 and the pad sacrificial film S_PAD.

Specifically, the first recess R1 may be formed in the select mold sacrificial film 112_1 and the pad sacrificial film S_PAD, and the second recess R2 may be formed in the non-select mold sacrificial film 112_2. The first recess R1 and the second recess R2 may be formed by the same process. In some implementations, the process of forming the first recess R1 and the second recess R2 may include a wet etching process using phosphoric acid, but the process is not limited thereto.

Since the first recess R1 is formed by removing the select mold sacrificial film 112_1 and the pad sacrificial film S_PAD, a height H1 of the first recess R1 may be greater than a height H2 of the second recess R2. The height as used herein may refer to a height in the third direction D3. Although a depth of the first recess R1 in the first direction D1 is the same as a depth of the second recess R2 in the first direction D1 in FIG. 18, the present disclosure is not limited thereto. For example, the width of the first recess R1 in the first direction D1 may be greater than the width of the second recess R2 in the first direction D1.

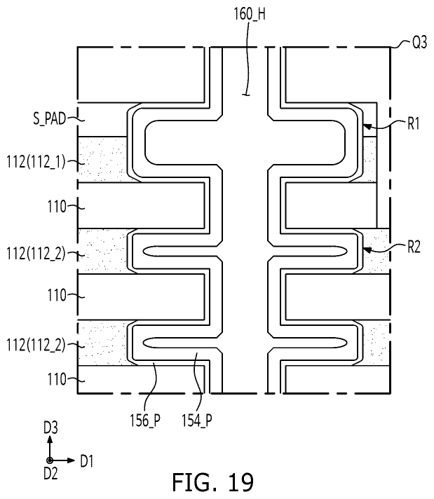

Referring to FIG. 19, a pre-liner insulating film 156_P and a pre-first insulating layer 154_P may be formed on the first through via hole 160_H, the first recess R1, and the second recess R2.

The pre-liner insulating film 156_P may extend along a profile of the first through via hole 160_H. In addition, the pre-liner insulating film 156_P may extend along the profile of the first recess R1 and the second recess R2. In some implementations, the pre-liner insulating film 156_P may be conformally formed.

The pre-first insulating layer 154_P may be formed on the pre-liner insulating film 156_P. The pre-first insulating layer 154_P may be formed along a profile of the pre-liner insulating film 156_P. The pre-first insulating layer 154_P may fill a portion of the first recess R1 and a portion of the second recess R2.

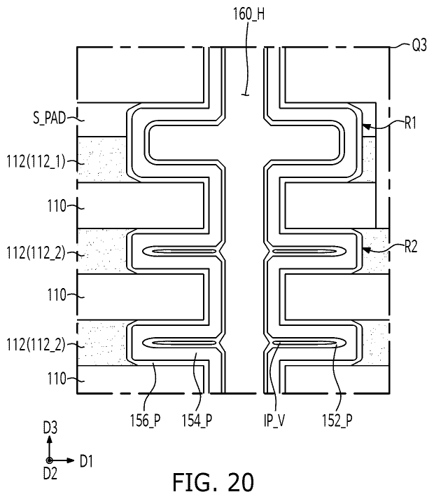

Referring to FIG. 20, a pre-second insulating layer 152_P may be formed on the pre-first insulating layer 154_P.

The pre-second insulating layer 152_P may extend along a profile of the pre-first insulating layer 154_P. The pre-second insulating layer 152_P may fill a portion of the first recess R1 and a portion of the second recess R2. In some implementations, a folding of the pre-second insulating layer 152_P may occur in the second recess R2 due to a relative height difference between the first recess R1 and the second recess R2. Accordingly, the first void IP_V may be formed in the pre-second insulating layer 152_P disposed on the second recess R2.

The pre-second insulating layer 152_P may include a material having etch selectivity with respect to the pre-first insulating layer 154_P. For example, the pre-second insulating layer 152_P may include silicon oxynitride or silicon nitride, and the pre-first insulating layer 154_P may include silicon oxide.

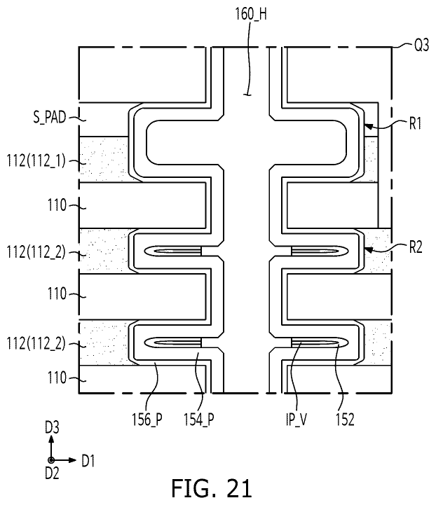

Referring to FIGS. 20 and 21, a portion of the pre-second insulating layer 152_P may be removed to form the first insulating layer 152.

Specifically, the pre-second insulating layer 152_P disposed on the first recess R1 may be entirely removed. On the other hand, a portion of the pre-second insulating layer 152_P disposed on the second recess R2 may be removed to form the first insulating layer 152. In some implementations, the first void IP_V may be exposed in the first insulating layer 152.

The process of removing a portion of the pre-second insulating layer 152_P may include a wet etching process using phosphoric acid, but the present disclosure is not limited thereto.

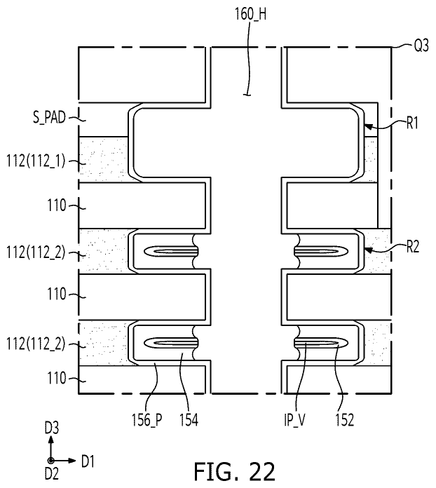

Referring to FIGS. 21 and 22, a portion of the pre-first insulating layer 154_P may be removed to form the second insulating layer 154.

Specifically, the pre-first insulating layer 154_P disposed on the first recess R1 may be entirely removed. On the other hand, a portion of the pre-first insulating layer 154_P disposed on the second recess R2 may be removed to form the second insulating layer 154. In some implementations, when the pre-first insulating layer 154_P disposed on the second recess R2 is removed, a portion of the first insulating layer 152 may be removed.

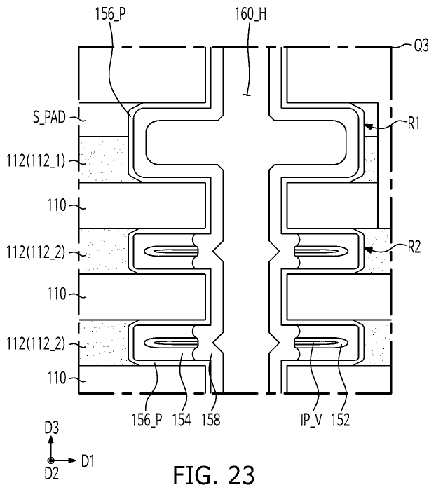

Referring to FIG. 23, a pre-first capping insulating layer 158 may be formed on the first through via hole 160_H, the first recess R1, and the second recess R2.

The pre-first capping insulating layer 158 may extend along the profile of the first through via hole 160_H. In addition, the pre-first capping insulating layer 158 may be formed on the pre-liner insulating film 156_P on the first recess R1. The pre-first capping insulating layer 158 may fill a portion of the first recess R1. The pre-first capping insulating layer 158 may fill the remaining portion of the second recess R2. In some implementations, the pre-first capping insulating layer 158 may include silicon oxide.

Referring to FIGS. 23 and 24, a portion of the pre-first capping insulating layer 158 may be removed to form the first capping layer CP_1.

Specifically, the pre-first capping insulating layer 158 disposed on the first recess R1 may be entirely removed. On the other hand, the pre-first capping insulating layer 158 disposed on the second recess R2 may be partially removed to form the first capping layer CP_1. In some implementations, the second void CP_V may be formed in the first capping layer CP_1.

The process of removing a portion of the pre-first capping insulating layer 158 may include a wet etching process using hydrogen fluoride (HF), but the present disclosure is not limited thereto.

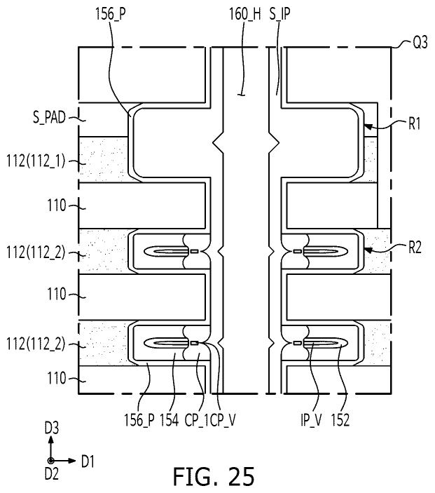

Referring to FIG. 25, a pre-second capping insulating layer S_IP may be formed on the first through via hole 160_H.

Specifically, the pre-second capping insulating layer S_IP may be formed on the pre-liner insulating film 156_P and the first capping layer CP_1. The pre-second capping insulating layer S_IP may fill the remaining portions of the first recess R1 and the second recess R2. In addition, the insulating material may fill at least a portion of the first through via hole 160_H. For example, the pre-second capping insulating layer S_IP may include silicon nitride or silicon oxynitride.

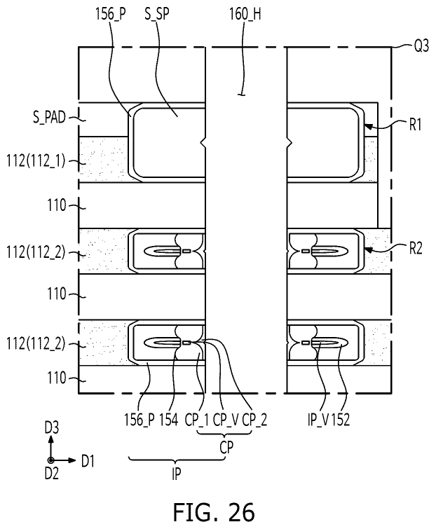

Referring to FIG. 26, a portion of the pre-second capping insulating layer S_IP may be removed by an etching process to form a sacrificial select pattern S_SP disposed on the first recess R1 and the second capping layer CP_2 disposed on the second recess R2. The second capping layer CP_2 may cover an exposed portion of the first capping layer CP_1 (e.g., a side surface of the first capping layer CP_1). A portion of the pre-liner insulating film 156_P may be removed by the process of removing the pre-second capping insulating layer S_IP. The first capping layer CP_1, the void CP_V, and the second capping layer CP_2 may form the capping pattern CP.

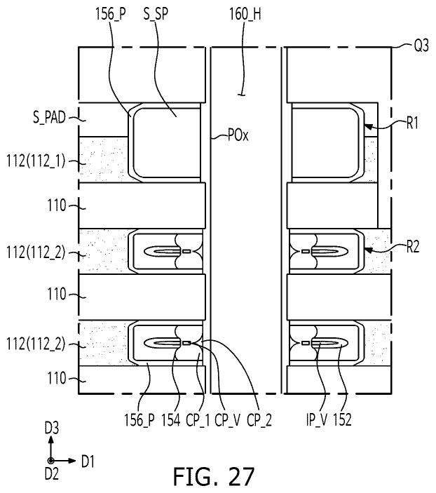

Referring to FIG. 27, a post oxide film (POx) may be formed in the first through via hole 160_H. The post oxide film (POx) may be formed on the first through via hole 160_H. The post oxide film (POx) may cover the sacrificial select pattern S_SP and the second capping layer CP_2.

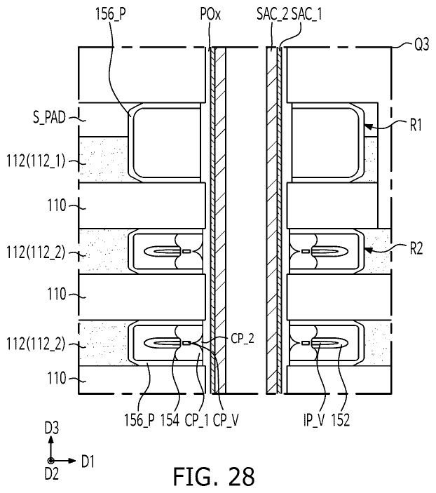

Referring to FIG. 28, a first through via sacrificial film SAC_1 and a second through via sacrificial film SAC_2 may be formed in the first through via hole 160_H. The first through via sacrificial film SAC_1 may be disposed on the post oxide film (POx) and may extend along a profile of the post oxide film (POx). In some implementations, the second through via sacrificial film SAC_2 may completely fill the inside of the first through via hole 160_H.

Referring to FIGS. 28 and 29, the first mold sacrificial film 112, the pad sacrificial film S_PAD, and the pre-liner insulating film 156_P may be removed, and the gate electrode 120 may be formed.

Specifically, the select mold sacrificial film 112_1, the pad sacrificial film S_PAD, and the sacrificial select pattern S_SP may be removed, and the first gate electrode 120_1 may be formed. In addition, the non-select mold sacrificial film 112_2 may be removed and the second gate electrode 120_2 may be formed.

The first gate electrode 120_1 may include the first filling conductive layer 122_1 and the first liner dielectric layer 124_1. The first liner dielectric layer 124_1 may surround the first filling conductive layer 122_1.

When the non-select mold sacrificial film 112_2 is removed, the pre-liner insulating film 156_P disposed on a sidewall of the non-select mold sacrificial film 112_2 may be partially removed. For example, the pre-liner insulating film 156_P disposed on the sidewall of the non-select mold sacrificial film 112_2 may be removed to expose the second insulating layer 154 and form the liner insulating layer 156. The second gate electrode 120_2 may be formed. The second gate electrode 120_2 may include the second filling conductive layer 122_2 and the second liner dielectric layer 124_2.

The post oxide film (POx), the first through via sacrificial film SAC_1, and the second through via sacrificial film SAC_2 may be removed. When the post oxide film (POx) is removed, the first liner dielectric layer 124_1 in contact with the post oxide film (POx) may be removed together. As a result, the first filling conductive layer 122_1 may be exposed.

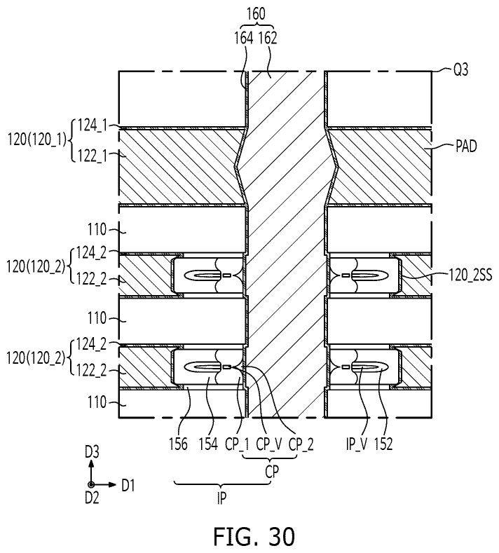

Referring to FIG. 30, the barrier conductive film 164 and the conductive pillar 162 may be sequentially formed to form the first through via 160. In some implementations, the second through via (170 in FIG. 2) may be formed simultaneously with the first through via 160.

In the process of forming the first through via 160, the capping pattern CP may be disposed on the first insulating layer 152 and the second insulating layer 154 to prevent penetration of the first through via 160. In addition, the dielectric constant of the first capping layer CP_1 is lower than that of the second capping layer CP_2. The insulating pattern IP may include the first capping layer CP_1 having a relatively low dielectric constant, thereby improving insulating characteristics between the second gate electrode 120_2 and the first through via 160. Accordingly, electrical characteristics and the reliability of the semiconductor memory device can be improved.

Referring to FIG. 2, the wiring contact 184 and the upper wiring structure 194 may be formed on the first through via 160 and the second through via 170. In addition, the bit line contact 182 and the bit line BL may be formed on the channel structure CH.

FIG. 31 is a block diagram of an example of an electronic system.

Referring to FIG. 31, an electronic system 1000 includes a semiconductor memory device 1100, which can be similar to the semiconductor memory devices described above with reference to FIGS. 1 to 15, and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive device (SSD), a universal serial bus (USB), a computing system, a medical device, or a communication device, which may include one or the plurality of semiconductor memory devices 1100.

For example, the semiconductor memory device 1100 may be the NAND flash memory device described above with reference to FIGS. 1 to 15. The semiconductor memory device 1100 may include a first structure 1100F and a second structure 1100S on the first structure 1100F. The first structure 1100F may be a peripheral circuit structure including the decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various embodiments.

In some implementations, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively. The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one select memory cell transistor from among the plurality of memory cell transistors MCT. The decoder circuit 1110 and the page buffer 1120 may be controlled by the logic circuit 1130. The semiconductor memory device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230, the electronic system 1000 may include a plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to predetermined firmware and may control the NAND controller 1220 to access the semiconductor memory device 1100. The NAND controller 1220 may include a NAND interface 1221 (or controller interface) that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. Upon receiving a control command from the external host through the host interface 1230, the processor 1210 may control the semiconductor memory device 1100 in response to the control command.

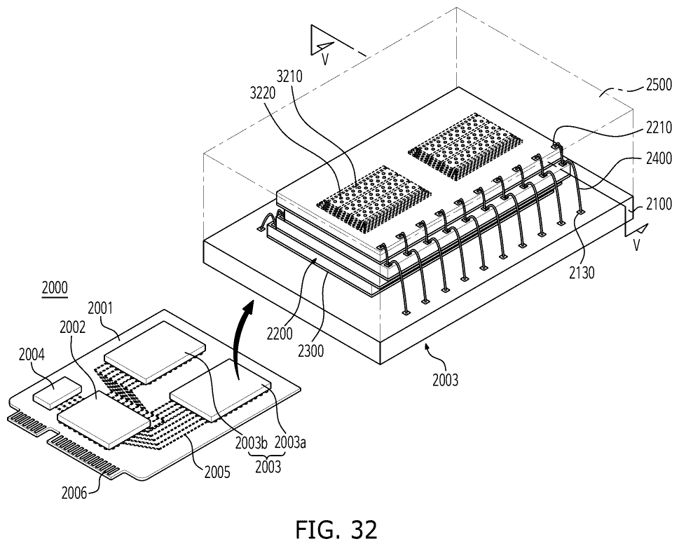

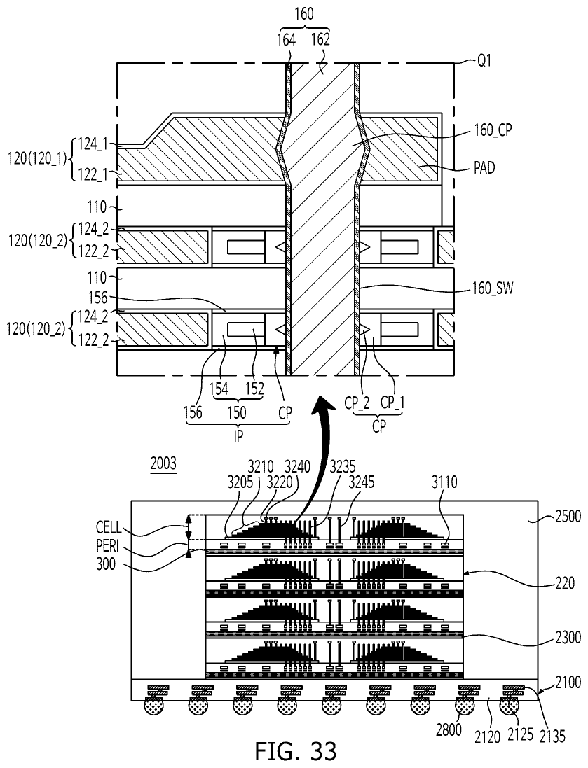

FIG. 32 is an example perspective view illustrating an electronic system 2000 including a semiconductor memory device. FIG. 33 is a schematic cross-sectional view taken along line V-V of FIG. 32.

Referring to FIGS. 32 and 33, the electronic system 2000 includes a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. In some implementations, the electronic system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some implementations, the electronic system 2000 may operate by the power supplied from the external host through the connector 2006. The electronic system 2000 may further include a Power Management Integrated Circuit (PMIC) that distributes the power supplied from the external host to the controller 2002 and the semiconductor package 2003.

The controller 2002 may record data in or read data from the semiconductor package 2003 and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory and may also provide a space for temporarily storing data in a control operation for the semiconductor package 2003. If the electronic system 2000 includes the DRAM 2004, in addition to the NAND controller for controlling the semiconductor package 2003, the controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input and output pad 2210. The input and output pad 2210 may correspond to the input and output pad 1101 of FIG. 31. Each of the semiconductor chips 2200 may include gate stack structures 3210, e.g., metal lines, and channel structures 3220. Each of the semiconductor chips 2200 may include the semiconductor memory device described above with reference to FIGS. 1 to 15.

In some implementations, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method and may be electrically connected to the package upper pads 2130 of the package substrate 2100. In some implementations, in each of the first and second semiconductor packages 2003a and 2003b, the semiconductor chips 2200 may be electrically connected to each other through a connection structure including through silicon via (TSV) instead of a bonding wire type connection structure 2400.

In some implementations, the controller 2002 and the semiconductor chips 2200 may be included in one package. In some implementations, the controller 2002 and the semiconductor chips 2200 may be mounted on a separate interposer substrate different from the main substrate 2001, and the controller 2002 and the semiconductor chips 2200 may be connected to each other through wiring formed on the interposer substrate.

In some implementations, the package substrate 2100 may be a printed circuit board. The package substrate 2100 may include a package substrate body portion 2120, the package upper pads 2130 disposed on an upper surface of the package substrate body portion 2120, lower pads 2125 disposed on a lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connection portions 2800, as illustrated in FIG. 25.

In an electronic system, each of the semiconductor chips 2200 may include the semiconductor memory device described above with reference to FIGS. 1 to 13. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 and a peripheral wiring 3110 described above with reference to FIGS. 1 to 13. In addition, for example, the cell structure CELL may include a common source line 3205, a gate stack structure 3210 on the common source line 3205, a channel structure 3220 and an isolation structure 3230 extending through the gate stack structure 3210, a bit line 3240 electrically connected to the channel structure 3220, and a gate connection wiring electrically connected to the word line of the gate stack structure 3210.

Each of the semiconductor chips 2200 may include a through wiring 3245 electrically connected to the peripheral wiring 3110 of the peripheral circuit structure PERI and extending into the cell structure CELL. The through wiring 3245 may be formed through the gate stack structure 3210 and may be further disposed outside the gate stack structure 3210. Each of the semiconductor chips 2200 may further include an input and output connection wiring 3265 electrically connected to the peripheral wiring 3110 of the peripheral circuit structure PERI and extending into a second structure 3200, and the input and output pad 2210 electrically connected to the input and output connection wiring 3265.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. What is claimed is:

1. A semiconductor memory device comprising:
a substrate including a cell array region and an extension region;
a plurality of gate electrodes on the substrate, wherein the plurality of gate electrodes are alternately stacked in a first direction perpendicular to an upper surface of the substrate, and the plurality of gate electrodes provide a staircase structure on the extension region;
a channel structure on the cell array region, wherein the channel structure extends through the plurality of gate electrodes in the first direction;
a first through via on the extension region, wherein the first through via extends through a first gate electrode of the plurality of gate electrodes and a second gate electrode of the plurality of gate electrodes, wherein the plurality of gate electrodes are between the first gate electrode and the substrate, and wherein the first through via is connected to the first gate electrode; and
an insulating pattern between the second gate electrode and a sidewall of the first through via, wherein the insulating pattern includes
an insulating structure on a sidewall of the second gate electrode,
a liner insulating layer on an upper surface of the insulating structure, and
a capping pattern between the insulating structure and the sidewall of the first through via,
wherein the insulating structure includes a first insulating layer and a second insulating layer surrounding the first insulating layer,
wherein the capping pattern includes a first capping layer disposed on the insulating structure, and a second capping layer between the first capping layer and the sidewall of the first through via, and
wherein a width of the second capping layer in the first direction decreases as a distance from the first through via increases.

2. The semiconductor memory device according to claim 1, wherein the first capping layer is in contact with the first insulating layer and the second insulating layer.

3. The semiconductor memory device according to claim 1, wherein the second capping layer includes a concave curved surface in contact with the first capping layer.

4. The semiconductor memory device according to claim 1, wherein the first capping layer includes a convex curved surface protruding toward the second insulating layer.

5. The semiconductor memory device according to claim 1, wherein the first capping layer includes a material different from that of the second capping layer.

6. The semiconductor memory device according to claim 1, wherein there is a first void in the first insulating layer.

7. The semiconductor memory device according to claim 1, wherein there is a second void in the first capping layer.

8. The semiconductor memory device according to claim 1, wherein the liner insulating layer is elongated in a second direction different from the first direction and covers an upper surface of the capping pattern.

9. The semiconductor memory device according to claim 1, wherein the first through via includes a conductive pillar extending in the first direction and a barrier conductive film surrounding the conductive pillar, and
wherein the conductive pillar includes a connection portion protruding toward the first gate electrode.

10. The semiconductor memory device according to claim 1, wherein the first gate electrode includes a first filling conductive layer and a first liner dielectric layer surrounding the first filling conductive layer, and
wherein the first filling conductive layer and the first liner dielectric layer are in contact with the first through via.

11. The semiconductor memory device according to claim 1, wherein the second gate electrode includes a second filling conductive layer and a second liner dielectric layer surrounding the second filling conductive layer, and
wherein the second liner dielectric layer is in contact with the liner insulating layer and the second insulating layer.

12. The semiconductor memory device according to claim 1, wherein a sidewall of the second gate electrode has a concave shape.

13. A semiconductor memory device comprising:
a substrate including a cell array region and an extension region;
a mold structure on the substrate, wherein the mold structure includes a plurality of gate electrodes alternately stacked with a plurality of mold insulating layers in a first direction perpendicular to an upper surface of the substrate, and the plurality of gate electrodes include a pad portion disposed in a staircase structure on the extension region;
a channel structure on the cell array region, wherein the channel structure extends through the plurality of gate electrodes in the first direction;
a first through via on the extension region, wherein the first through via extends through a pad portion of a first gate electrode of the plurality of gate electrodes and through a second gate electrode of the plurality of gate electrodes, wherein the second gate electrode is between the first gate electrode and the substrate, and wherein the first through via is electrically connected to the pad portion of the first gate electrode; and
an insulating pattern between the second gate electrode and the first through via, wherein the insulating pattern surrounds a portion of a sidewall of the first through via, wherein the insulating pattern includes
an insulating structure including a first insulating layer and a second insulating layer surrounding three surfaces of the first insulating layer, and
a capping pattern between the insulating structure and the sidewall of the first through via,
wherein the capping pattern includes a first capping layer covering a first side of an insulating structure defined by a side surface of the first insulating layer and a side surface of the second insulating layer, and includes a second capping layer between the first capping layer and the sidewall of the first through via, and
wherein a width of the second capping layer in the first direction decreases as a distance from the first through via increases.

14. The semiconductor memory device according to claim 13, wherein the insulating structure includes the first side and a second side facing the first side in a second direction different from the first direction, and
wherein the second side of the insulating structure is in contact with the second gate electrode.

15. The semiconductor memory device according to claim 13, wherein a thickness of the pad portion of the first gate electrode is greater than a thickness of a plate of the first gate electrode.

16. The semiconductor memory device according to claim 13, further comprising:
a first liner insulating layer on an upper surface of the insulating pattern and on an upper surface of the capping pattern; and
a second liner insulating layer on a lower surface of the insulating pattern and on a lower surface of the capping pattern.

17. The semiconductor memory device according to claim 16, wherein the second capping layer covers at least a portion of the sidewall of the first through via exposed between the first liner insulating layer and the second liner insulating layer.

18. The semiconductor memory device according to claim 13, further comprising a peripheral circuit structure on a lower surface of the substrate, where the lower surface faces the upper surface of the substrate,
wherein the first through via extends through the substrate and is connected to the peripheral circuit structure.

19. The semiconductor memory device according to claim 13, wherein the first through via includes
a conductive pillar extending in the first direction,
a barrier conductive film surrounding the conductive pillar, and
a connection portion protruding toward the first gate electrode.

20. An electronic system, comprising:
a first substrate;
a semiconductor memory device on the first substrate, wherein the semiconductor memory device includes a peripheral circuit structure and a cell structure stacked on the peripheral circuit structure; and
a controller on the first substrate, wherein the controller is electrically connected to the semiconductor memory device, wherein the cell structure includes
a second substrate including a cell array region and an extension region,
a plurality of gate electrodes on the second substrate, wherein the plurality of gate electrodes are alternately stacked in a first direction perpendicular to an upper surface of the second substrate, and the plurality of gate electrodes provide a staircase structure on the extension region,
a channel structure on the cell array region, wherein the channel structure is extends through the plurality of gate electrodes in the first direction,
a first through via extending through a first gate electrode of the plurality of gate electrodes and through a second gate electrode of the plurality of gate electrodes, wherein the second gate electrode is between the first gate electrode and the second substrate, wherein the first through via is connected to the first gate electrode, and
an insulating pattern between the second gate electrode and a sidewall of the first through via,
wherein the first through via extends through the second substrate and is connected to the peripheral circuit structure, and the insulating pattern includes
an insulating structure disposed on a sidewall of the second gate electrode and including a first insulating layer and a second insulating layer surrounding the first insulating layer,
a liner insulating layer on an upper surface of the insulating structure, and
a capping pattern between the insulating structure and the sidewall of the first through via,
wherein the capping pattern includes a first capping layer on the insulating structure, and a second capping layer between the first capping layer and the sidewall of the first through via, and
wherein a width of the second capping layer in the first direction decreases as a distance from the first through via increases.
